(19) United States
(12) Patent Application Publication
(10) Pub. No.: US 2025/0074382 A1
(43) Pub. Date: Mar. 6, 2025

(54) SYSTEM AND METHOD FOR PARKING CONTROL OF VEHICLE

(71) Applicants: Hyundai Motor Company, Seoul (KR); Kia Corporation, Seoul (KR)

(72) Inventors: Sang Weol Han, Seoul (KR); Yun Sup Shin, Seoul (KR); Sang Yoon Bang, Seoul (KR); Jin Yong Kim, Seoul (KR)

(21) Appl. No.: 18/775,037

(22) Filed: Jul. 17, 2024

(30) Foreign Application Priority Data
Aug. 31, 2023 (KR) 10-2023-0115428

(51) Int. Cl. B60T 15/02; B60T 7/12; B60T 17/22; G01R 31/36; G01R 31/3835

(52) U.S. Cl. CPC B60T 15/027; B60T 7/12; B60T 17/22; G01R 31/3647; G01R 31/3835

(57) ABSTRACT

According to an embodiment of the present disclosure, there is provided a method of controlling parking of a vehicle, the method comprising detecting whether a battery power supplied to an electronic parking brake (EPB) controller is less than or equal to a reference voltage, the EPB configured to control a flow of compressed air to generate a brake force based on a pressure of the compressed air, and if the battery power is less than or equal to the reference voltage, discharging the compressed air outside by opening at least one orifice hole.

### CROSS-REFERENCE TO THE RELATED APPLICATION

This application claims under 35 U.S.C. § 119 (a) the benefit of Korean Patent Application No. 10-2023-0115428, filed on Aug. 31, 2023, which is hereby incorporated by reference as if fully set forth herein.

### BACKGROUND

### Technical Field

The present disclosure relates to a system and method for controlling parking of a vehicle.

### Background

A vehicle is generally equipped with a brake device to slow down or stop the vehicle. The brake device may be divided into a driving brake used to decelerate and stop the vehicle while in motion, and a parking brake used to park or stop the vehicle. The parking brake, designed to prevent movement of a stationary vehicle, is commonly implemented through an electronic parking brake (EPB) system.

The EPB system, a system that operates the parking brake electronically through a simple switch operation, may control the operation of an EPB valve by a parking brake activation signal transmitted from an EPB controller according to the driver selecting an EPB switch to provide and release a brake force to and from the parking brake.

However, if the vehicle's battery falls below the EPB operating voltage, the EPB controller may not function. As a result, it may become impossible to activate or release the parking brake using the EPB switch.

### SUMMARY OF THE PRESENT DISCLOSURE

An object of the present disclosure is to provide a vehicle parking control system and its control method that may ensure the safety of a vehicle even in the case of a loss of a parking brake function that uses an electronic parking brake (EPB) system due to a low-voltage state of the vehicle.

The technical objects to be achieved by the present disclosure are not limited to those described above, and other technical objects not described above may also be clearly understood by those skilled in the art from the following description.

According to an embodiment of the present disclosure, there is provided a method of controlling parking of a vehicle, the method comprising detecting, by a low-voltage detector, whether a battery power supplied to an electronic parking brake (EPB) controller is less than or equal to a reference voltage, the EPB configured to control a flow of compressed air to generate a brake force based on a pressure of the compressed air, and if the battery power is detected to be less than or equal to the reference voltage, discharging, by a solenoid valve, the compressed air into atmosphere by opening at least one orifice hole.

In at least one embodiment of the present disclosure, the detecting of whether the battery power is less than or equal to the reference voltage comprises entering an on state and supplying current if the battery power exceeds the reference voltage, and entering an off state and blocking the current supply if the battery power is less than or equal to the reference voltage, wherein the discharging of the compressed air outside comprises when the current supply is blocked, opening the orifice hole by a solenoid valve to discharge the compressed air into atmosphere, wherein the discharging of the compressed air into atmosphere further comprises when the current is supplied, blocking the discharging of the compressed air by the solenoid valve receiving the current.

In at least one embodiment of the present disclosure, the vehicle comprises an air tank configured to store therein the compressed air, a hydraulic line configured to transfer the compressed air of the air tank, an EPB valve configured to receive the compressed air through the hydraulic line and block or pass the flow of the compressed air according to a control signal from the EPB controller, an EPB chamber configured to generate a brake force based on the pressure of the compressed air supplied through the EPB valve, a branch line branched from the hydraulic line, and a solenoid valve interposed in the branch line and configured to open the at least one orifice hole to discharge the compressed air into atmosphere when the battery power is less than or equal to the reference voltage.

In at least one embodiment of the present disclosure, the detecting of whether the battery power is less than or equal to the reference voltage comprises supplying current to the solenoid valve as a switch is turned on if the battery power exceeds the reference voltage, and blocking the current supply to the solenoid valve as the switch is turned off if the battery power is less than or equal to the reference voltage.

In at least one embodiment of the present disclosure, the solenoid valve comprises a coil configured to receive the current under the control of the voltage detector, a spring interposed in the coil and a rod configured to block the orifice hole by moving in a direction that presses the spring when the current is supplied to the coil, and open the orifice hole by moving in an opposite direction by an elastic restoring force of the spring when the current supply is blocked.

In at least one embodiment of the present disclosure, the rod comprises a first rod member configured to move with a linear displacement outside the branch line based on whether the coil is energized, a second rod member having the orifice hole formed therein, and inserted into an inner space of the branch line through an opening formed in the branch line to block the compressed air or open the orifice hole, and a connecting member configured to connect the first rod member and the second rod member.

In at least one embodiment of the present disclosure, the method further comprises supplying the current by the switch being turned on, if the battery power exceeds the reference voltage, and when the current is supplied to the coil of the solenoid valve and the first rod member moves in an outer direction of the branch line to press the spring, and the second rod member is pulled out through the opening formed in the branch line by the movement of the first rod member, closing the orifice hole.

In at least one embodiment of the present disclosure, the method further comprises blocking the current supply by the switch being turned off, if the battery power is less than or equal to the reference voltage, and when the current supply to the coil of the solenoid valve is blocked and the first rod member moves in an inner direction of the branch line by the elastic restoring force of the spring, and the second rod member is inserted into the branch line through the opening formed in the branch line by the movement of the first rod member, opening the orifice hole.

In at least one embodiment of the present disclosure, the method further comprises discharging the compressed air stored in the air tank outside through the orifice hole of the branch line, reducing an air pressure in the air tank and the EPB chamber, and generating a parking brake force by the reduced air pressure in the EPB chamber.

In some embodiments, the reference voltage may be 16V.

According to an embodiment of the present disclosure, there is provided a parking control system of a vehicle, an electronic parking brake (EPB) controller configured to control a flow of compressed air to generate a brake force based on a pressure of the compressed air, a low-voltage detector configured to detect whether a battery power supplied to the EPB controller is less than or equal to a reference voltage, and a solenoid valve configured to discharge the compressed air into atmosphere if the battery power is detected to be less than or equal to the reference voltage.

In the system of at least one embodiment of the present disclosure, the parking control system may further comprise an air tank configured to store therein the compressed air, a hydraulic line configured to transfer the compressed air of the air tank, an EPB valve configured to receive the compressed air through the hydraulic line, and block or pass the flow of the compressed air according to a control signal from the EPB controller, an EPB chamber configured to generate a brake force according to the pressure of the compressed air supplied through the EPB valve, and a branch line branched from the hydraulic line, wherein the solenoid valve is interposed in the branch line, and configured to discharge the compressed air into atmosphere by opening at least one orifice hole when the battery power is less than or equal to the reference voltage.

In the system of at least one embodiment of the present disclosure, the low-voltage detector is configured to be turned on or off according to the battery power to supply or block current, and the solenoid valve is configured to block or discharge the compressed air based on whether the current is supplied or blocked.

In the system of at least one embodiment of the present disclosure, the low-voltage detector comprises a switch configured to be turned on to supply the current if the battery power exceeds the reference voltage, and be turned off to block the current supply if the battery power is less than or equal to the reference voltage.

In the system of at least one embodiment of the present disclosure, the solenoid valve comprises a coil configured to receive the current under the control of the low-voltage detector, a spring interposed in the coil, and a rod configured to block the orifice hole by moving in a direction that presses the spring when the current is supplied to the coil, and open the orifice hole by moving in an opposite direction by an elastic restoring force of the spring when the current supply is blocked.

In the system of at least one embodiment of the present disclosure, the rod comprises a first rod member configured to move with a linear displacement outside the branch line depending on whether the current is supplied to the coil, a second rod member having the orifice hole formed therein, and inserted into an inner space of the branch line through an opening formed in the branch line to block the compressed air or open the orifice hole, and a connecting member configured to connect the first rod member and the second rod member.

In the system of at least one embodiment of the present disclosure, the rod is configured to if the current is supplied to the coil and the first rod member moves in an outer direction of the branch line to press the spring, and the second rod member is pulled out through the opening formed in the branch line by the movement of the first rod member, close the orifice hole.

In the system of at least one embodiment of the present disclosure, the rod is configured to if the current supply to the coil is blocked, the first rod member moves in an inner direction of the branch line by the elastic restoring force of the spring, and the second rod member is inserted into the branch line through the opening formed in the branch line by the movement of the first rod member, open the orifice hole.

In the system of at least one embodiment of the present disclosure, the voltage detector comprises a first current supply line configured to apply current to the coil, and a second current supply line configured to receive the current of the coil, wherein the switch is interposed in the first current supply line.

The embodiments of the present disclosure have the following effects.

According to the embodiments of the present disclosure described herein, the parking control system and its control method may ensure the safety of a vehicle even in the case of a loss of a parking brake function that uses an EPB system due to a low-voltage state of the vehicle.

The parking control system and its control method may have an additional pipe installed for air discharge in a parking air tank for driving a parking brake and control the air discharge of the parking air tank through the additional pipe when the vehicle is in a low-voltage state where a voltage is less than or equal to a reference voltage, thereby securing a fail-safe backup function in preparation for the loss of the parking brake function in the event of an electrical function failure of an EPB system.

The effects that can be achieved from the present disclosure are not limited to those described above, and other effects not described above may also be clearly understood by those skilled in the art from the following description.

### BRIEF DESCRIPTION OF THE DRAWINGS

FIG. 1 is a block diagram schematically illustrating a vehicle including a parking control system according to an embodiment of the present disclosure.

FIG. 2 is a diagram illustrating an operation of a solenoid valve.

FIG. 3 is a diagram illustrating a configuration of an emergency parking control device according to an embodiment of the present disclosure.

FIGS. 4 and 5 are diagrams illustrating a method of operating the emergency parking control device of FIG. 3.

FIGS. 6 and 7 are flowcharts illustrating a parking control method of a vehicle according to an embodiment of the present disclosure.

### DETAILED DESCRIPTION OF THE DISCLOSURE

Hereinafter, embodiments of the present disclosure will be described in detail with reference to the accompanying drawings. The embodiments are not construed as limited to the disclosure and should be understood to include all changes, equivalents, and replacements within the idea and the technical scope of the disclosure.

In the description of the embodiments, when an element is described as formed “above/on” or “below/under” another element, it may be construed that they are in direct contact, or they are in indirect contact with one or more other elements disposed therebetween.

In this case, the use of “above/on” or “below/under” may be based on what is shown in the accompanying drawings, and these terms are used only to indicate a relative positional relationship between elements for the convenience of description but may not be used to limit the actual positions of the elements.

In addition, terms including ordinal numbers such as “first,” “second,” and the like may be used herein to describe various elements, the elements are not limited by these terms. These terms are only used to distinguish one element from another.

It is to be further understood that the terms “comprises/comprising” and/or “includes/including” used herein specify the presence of a stated element, but do not preclude the presence or addition of one or more other elements. Further, in describing the embodiments, when it is determined that a detailed description of related publicly known technology may obscure the gist of the embodiments disclosed herein, the detailed description thereof will be omitted.

According to an embodiment of the present disclosure, a vehicle may be equipped with an electronic parking brake (EPB) system. The EPB system may activate or release a parking brake by activating a parking chamber using an air pressure and a spring when a driver selects a parking brake function.

According to an embodiment of the present disclosure, the safety of a vehicle can be ensured even if the parking brake function of an EPB system is lost due to a low-voltage state. This is achieved by installing an additional pipe for air discharge in a parking air tank that drives the parking brake, and controlling the compressed air in the parking air tank to be discharged through an orifice hole in the additional pipe when the vehicle's voltage is less than or equal to a reference voltage.

Hereinafter, a vehicle parking control system and a control method thereof according to an embodiment of the present disclosure will be described in detail with reference to the accompanying drawings.

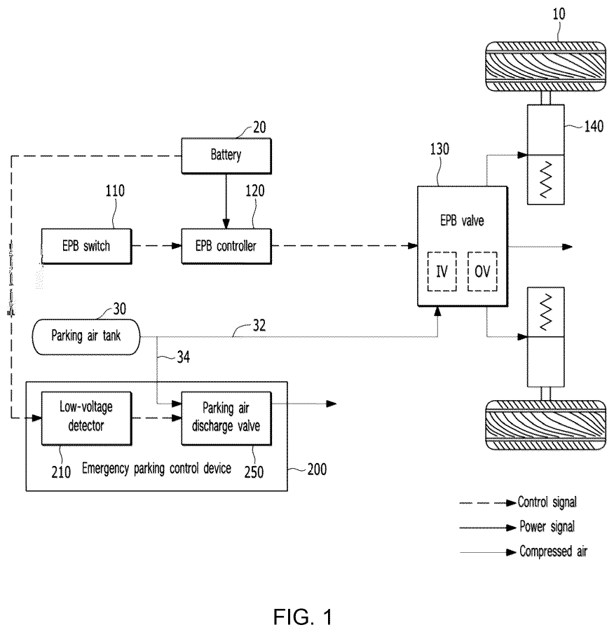

FIG. 1 is a block diagram schematically illustrating a vehicle including a parking control system according to an embodiment of the present disclosure.

Referring to FIG. 1, the vehicle may include a driving wheel 10 and a battery 20, and may include an EPB switch 110, an EPB controller 120, an EPB valve 130, an EPB chamber 140, and a parking air tank 30 for operating an EPB system. According to an embodiment of the present disclosure, the vehicle may also include an emergency parking control device 200 configured to operate when a voltage of the battery 20 (also referred to herein as a battery voltage or battery power) is less than or equal to a reference voltage.

The functions of the EPB system may be implemented by the EPB switch 110, the EPB controller 120, the EPB valve 130, the EPB chamber 140, and the parking air tank 30.

The parking air tank 30 may store therein high-pressure compressed air. For example, the parking air tank 30 may store therein compressed air with a pressure of 5 bar or more.

The EPB switch 110 may be installed around the driver's seat to receive parking brake “on/off” being selected. The driver may select the activation of a parking brake by selecting “parking brake on” through the EPB switch 110 and may select the release of the parking brake by selecting “parking brake off.”

The EPB controller 120 may output a parking brake on/off control signal to the EPB valve 130 according to a signal output from the EPB switch 110. The EPB controller 120 may operate by receiving a driving voltage from the battery 20. The driving voltage of the EPB controller 120 may be set to be in a specific voltage range. For example, when the driving voltage is set between 16 volts (V) and 32V, the EPB controller 120 may operate by receiving a driving voltage in the voltage range from the battery 20, and when the supply voltage of the battery 20 is 16V or less, the EPB controller 120 may not be able to operate.

The EPB valve 130 may receive the compressed air from the parking air tank 30 through a hydraulic line 32, and selectively activate an inlet solenoid valve IV and an outlet solenoid valve OV therein according to the parking brake on/off control signal to pass or block the compressed air.

When the “parking brake off” control signal is input, the EPB valve 130 may open the inlet solenoid valve IV and close the outlet solenoid valve OV. When the “parking brake on” control signal is input, the EPB valve 130 may close the inlet solenoid valve IV and open the outlet solenoid valve OV.

The EPB chamber 140 may generate or release a brake force of the parking brake by using an air pressure flowing in or out through the EPB valve 130 and an elastic force of a spring. When the “parking brake off” control signal is input to the EPB valve 130 and the inlet solenoid valve IV is opened, the compressed air may flow into the EPB chamber 140 to compress the spring, and thus the brake force against the driving wheel 10 may be released. When the “parking brake on” control signal is input to the EPB valve 130 and the inlet solenoid valve IV is closed, the pressure in the EPB chamber 140 may decrease to expand the spring, and thus the brake force against the driving wheel 10 may be generated.

In the EPB system with this configuration, the EPB controller 120 may output a “parking brake on” control signal or a “parking brake off” control signal to the EPB valve 130 according to a signal of the EPB switch 110 to generate or release the brake force of the parking brake. However, since the EPB controller 120 operates by receiving the driving voltage from the battery 20, if the supply voltage of the battery 20 drops below the required driving voltage due to an emergency such as an alternator failure or an electrical fire, the EPB controller 120 may become inoperable.

Accordingly, the vehicle according to an embodiment of the present disclosure may further include the emergency parking control device 200 configured to operate when the voltage of the battery 20 is less than or equal to the reference voltage.

The emergency parking control device 200 may include a parking air discharge valve 250 interposed in a branch line 34 branched from the hydraulic line 32 and configured to pass or block the compressed air, and a low-voltage detector 210 configured to detect a low-voltage state of the battery 20 and control an operation of the parking air discharge valve 250.

When the voltage of the battery 20 is less than or equal to the reference voltage, the low-voltage detector 210 may control an orifice hole to be opened by the parking air discharge valve 250. The reference voltage at which the parking air discharge valve 250 is opened may be set based on the driving voltage of the EPB controller 120. For example, when the EPB controller 120 is in an inoperable state at a voltage of 16V or less, the low-voltage detector 210 may detect the voltage of 16V or less and control the orifice hole to be opened by the parking air discharge valve 250.

The parking air discharge valve 250 may gradually reduce the air pressure of the parking air tank 30 and the EPB chamber 140 by discharging the compressed air from the branch line 34 through the orifice hole. The parking air discharge valve 250 may be implemented using a solenoid valve.

Since the parking brake of the vehicle that is currently traveling is in an off state, the inlet solenoid valve IV of the EPB valve 130 may be opened to allow the compressed air to flow into the EPB chamber 140, and the spring may thus be compressed. That is, the parking air tank 30 and the EPB chamber 140 may be connected through the hydraulic line 32, and the EPB chamber 140 may then be maintained in a high-pressure state. Accordingly, when the compressed air is gradually discharged through the parking air discharge valve 250 of the branch line 34, the air pressure in the parking air tank 30 and the EPB chamber 140 may gradually decrease. As the pressure in the EPB chamber 140 gradually decreases, the parking brake may also gradually operate. In this case, that the parking brake gradually operates may indicate that, rather than the vehicle is immediately braked as the compressed air is discharged through the branch line 34, a predetermined period of time is consumed until the vehicle is completely braked after the compressed air is discharged gradually and the parking brake force increases gradually. That is, when the EPB controller 120 is in an inoperable state due to a low-voltage state of the battery 20, the emergency parking control device 200 may operate, which may allow the parking brake to operate with a time lag, the vehicle may then be braked. In the meantime, the driver may move the vehicle to a safe space.

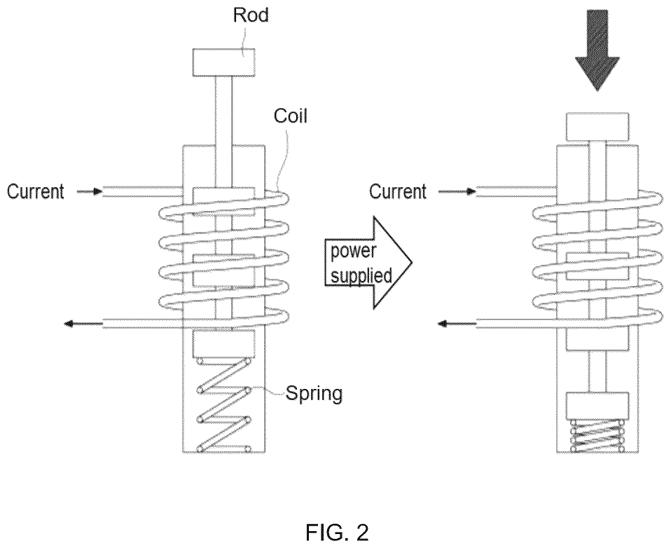

FIG. 2 is a diagram illustrating an operation of a solenoid valve, in which a magnetic solenoid valve that is applicable to implement the parking air discharge valve 250 is provided as an example.

Referring to FIG. 2, the magnetic solenoid valve may include a rod that operates with a linear displacement, a spring that provides an elastic restoring force to the rod, and a coil wound around the rod. In the magnetic solenoid valve with this configuration, when current is supplied to the coil and the coil is energized, the rod may move up and down according to Fleming's left-hand rule.

When current is supplied to the coil in which a + pole is connected to the top of the coil and a − pole is connected to the bottom of the coil in the magnetic solenoid valve shown in FIG. 2, the rod may move linearly in a downward direction that presses the spring according to Fleming's left-hand rule. When the current supply is stopped, the rod may move to its original position by the elastic restoring force of the spring.

The emergency parking control device 200 may be configured using the magnetic solenoid valve having these driving characteristics described above.

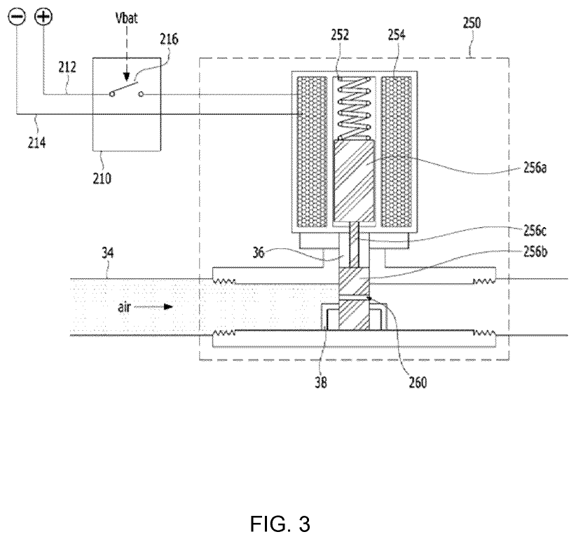

FIG. 3 is a diagram illustrating a configuration of an emergency parking control device according to an embodiment of the present disclosure.

According to an embodiment of the present disclosure, the emergency parking control device 200 may include the low-voltage detector 210 and the parking air discharge valve 250.

The parking air discharge valve 250 may be interposed in the branch line 34 which branches from hydraulic line 32, to control the flow of compressed air—either blocking it or allowing it to discharge. When it discharges the air through an orifice hole, it gradually lowers the air pressure in both the parking air tank 30 and the EPB chamber 140. This reduction in pressure provides sufficient time for the vehicle to move to a safe location before the parking brake is activated. A parking brake operation time, a time at which the parking brake operates, may be determined by the pressure in the EPB chamber 140 and a constant of the spring. Therefore, the parking brake operation time may be controlled by adjusting a pressure drop rate by adjusting the size or number of orifice holes.

The parking air discharge valve 250 may include: a solenoid valve including a rod 256 that operates with a linear displacement, a spring 252 that provides an elastic restoring force to the rod 256, and a coil 254 that is wound around the rod 256; and a fixing member 258 that fixes the solenoid valve to an opening 36 formed in the branch line 34.

The rod 256 may include: a first rod member 256a that moves with a linear displacement outside the branch line 34 depending on whether current is applied to the coil 254; a second rod member 256b that includes at least one orifice hole 260 and is configured to be inserted into an inner space of the branch line 34 through the opening 36 of the branch line 34 to block compressed air or open the orifice hole 260; and a connecting member 256c that connects the first rod member 256a and the second rod member 256b.

The first rod member 256a may be positioned in the inner space of the spring 252 and the coil 254. The first rod member 256a may move with a linear displacement in a direction perpendicular to the branch line 34 outside the branch line 34 depending on whether the coil 254 is energized. When current is input to the coil 254, the first rod member 256a may receive a force in a direction that presses the spring 252, that is, in an outer direction of the branch line 34. When the current input to the coil 254 is stopped, the first rod member 256a may move in an inner direction of the branch line 34 by the elastic restoring force of the spring 252.

The second rod member 256b may be connected to the first rod member 256a through the connecting member 256c to move linearly in the same way as the first rod member 256a in the inner space of the branch line 34. When the first rod member 256a moves in the inner direction of the branch line 34, the second rod member 256b may be completely inserted into the inner space of the branch line 34 through the opening 36 of the branch line 34 to open the orifice hole 260. When the first rod member 256a moves in the outer direction of the branch line 34, the second rod member 256b may move the opening 36 with a partial area being pulled out to close the orifice hole 260. That is, when the second rod member 256b is only partially inserted into the inner space of the branch line 34, the orifice hole 260 may be positioned outside the branch line 34 and closed. When the second rod member 256b is completely inserted into the inner space of the branch line 34, the orifice hole 260 may be positioned inside the branch line 34 to discharge the compressed air.

In the inner space of the branch line 34, a support portion 38 may be formed. This protrudes from an inner wall of the branch line 34 to guide the movement the second rod member 256b to be inserted through the opening 36 and support the second rod member 256b inserted in the inner space of the branch line 34.

When only the partial area of the second rod member 256b is inserted into the inner space of the branch line 34, the support portion 38 may support an end of the second rod member 256b and block a remaining area that is not blocked by the second rod member 256b in the inner space of the branch line 34. That is, when only the partial area of the second rod member 256b is inserted into the inner space of the branch line 34, the orifice hole 260 may be positioned in an outer space of the branch line 34 and the compressed air of the branch line 34 may be completely blocked by the second rod member 256b and the support portion 38.

When the second rod member 256b is completely inserted into the inner space of the branch line 34, the partial area of the second rod member 256b may be seated within the support portion 38, and the remaining area may be exposed to the inner space of the branch line 34. Accordingly, the partial area of the second rod member 256b may be shielded by the support portion 38, and the remaining area may be exposed to the inner space of the branch line 34. The orifice hole 260 may be positioned in the inner space of the branch line 34 and may thus discharge the compressed air from the branch line 34.

When a battery voltage Vbat exceeds a reference voltage, the low-voltage detector 210 may control the parking air discharge valve 250 to block the branch line 34 such that the compressed air is not discharged. In the case of a low-voltage state with a voltage less than or equal to the reference voltage, the low-voltage detector 210 may control the parking air discharge valve 250 to open the orifice hole 260, which allows the compressed air of the branch line 34 to be gradually discharged.

The low-voltage detector 210 may include current supply lines 212 and 214 that supply current to the coil 254 of the parking air discharge valve 250 and a switch 216 that is turned on/off according to the battery voltage Vbat to connect or disconnect the current supply lines 212 and 214.

The current supply lines 212 and 214 may include a + current supply line 212 that applies current to the coil 254 and a − current supply line 214 that receives current from the coil 254. Accordingly, the current applied through the + current supply line 212 may pass through the coil 254 and may then be applied to the − current supply line 214, thereby energizing the coil 254.

When the battery voltage Vbat exceeds the reference voltage, the switch 216 may be turned on to energize the current supply lines 212 and 214. When the battery voltage Vbat is less than or equal to the reference voltage, the switch 216 may be turned off to disconnect the current supply lines 212 and 214. The switch 216 may be interposed in the + current supply line 212 that applies current to the coil 254.

With the configuration described above, when the battery voltage Vbat exceeds the reference voltage, the switch 216 of the low-voltage detector 210 may be turned on to energize the coil 254 of the parking air discharge valve 250, and may thereby block the orifice hole 260 of the second rod member 256b to block the discharge of the compressed air. In addition, when the battery voltage Vbat falls to or below the reference voltage, the switch 216 of the low-voltage detector 210 may be turned off, thereby stopping the current input to the coil 254. Accordingly, the first rod member 256a may move in the inner direction of the branch line 34 by the elastic restoring force of the spring 252, and the second rod member 256b may then be completely inserted into the inner space of the branch line 34. The orifice hole 260 may thus be opened to discharge the compressed air of the branch line 34.

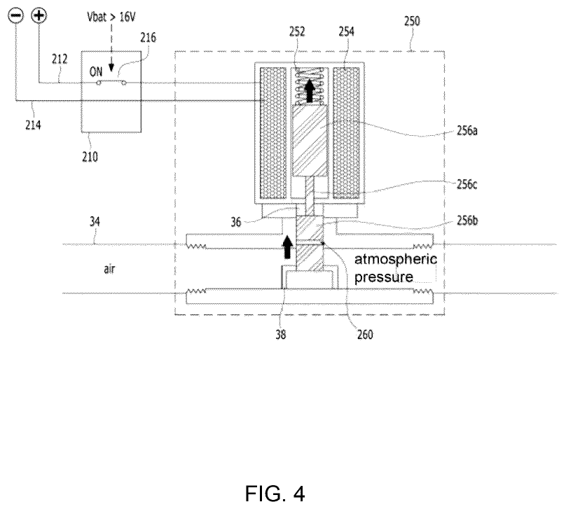

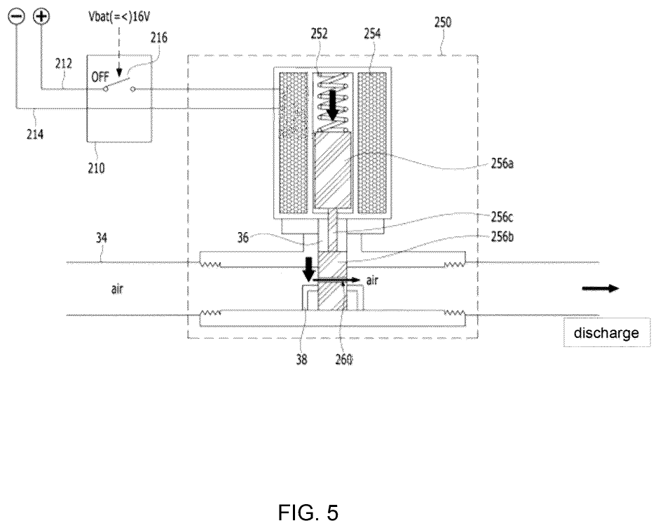

FIGS. 4 and 5 are diagrams illustrating a method of operating the emergency parking control device of FIG. 3. FIG. 4 is a diagram illustrating an operation performed by the emergency parking control device when a battery voltage Vbat exceeds a reference voltage, and FIG. 5 is a diagram illustrating an operation performed by the emergency parking control device when the battery voltage Vbat is less than or equal to the reference voltage. The reference voltage may be set to a voltage at which the EPB controller 120 switches to an inoperable state. For example, the reference voltage may be set to 16V.

Referring to FIG. 4, when the battery voltage Vbat exceeds the reference voltage of 16V, the parking air discharge valve 250 may block the branch line 34 to prevent compressed air from being discharged.

When the battery voltage Vbat exceeds 16V, the switch 216 of the low-voltage detector 210 may be turned on to connect the + current supply line 212. Accordingly, the current applied through the + current supply line 212 may pass through the coil 254 of the parking air discharge valve 250 and may then be applied to the − current supply line 214 to energize the coil 254.

When the current is supplied to the coil 254 of the parking air discharge valve 250, a force may be applied to the first rod member 256a in a direction that presses the spring 252 according to Fleming's left-hand rule. When the first rod member 256a moves in the direction that presses the spring 252, that is, in an outer direction of the branch line 34, the second rod member 256b may only be partially inserted through the opening 36, and another portion thereof may move to be pulled out to an outer area of the branch line 34.

When the second rod member 256b is only partially inserted into the inner space of the branch line 34, the orifice hole 260 may be positioned in the outer space of the branch line 34. The support portion 38 in the inner space of the branch line 34 may support the end of the second rod member 256b, while blocking a remaining area of the inner space of the branch line 34 that is not blocked by the second rod member 256b. Accordingly, the compressed air in the branch line 34 may be completely blocked by the second rod member 256b and the support portion 38.

As described above, when the battery voltage Vbat exceeds the reference voltage of 16V, the parking air discharge valve 250 may block the branch line 34 to prevent the compressed air from being discharged. When the battery voltage Vbat exceeds the reference voltage of 16V, the EPB system may operate normally, and the EPB controller 120 may output, to the EPB valve 130, a “parking brake on” control signal or a “parking brake off” control signal according to a signal of the EPB switch 110 to generate or release a brake force of the parking brake.

Referring to FIG. 5, when the battery voltage Vbat is less than or equal to the reference voltage of 16V, the parking air discharge valve 250 may discharge compressed air of the branch line 34 into the atmosphere through the orifice hole 260. Accordingly, an air pressure of the parking air tank 30 and the EPB chamber 140 connected to the branch line 34 may gradually decrease, and the spring of the EPB chamber 140 may gradually expand, allowing the parking brake to gradually operate.

When the battery voltage Vbat drops to the voltage of 16V or less, the switch 216 of the low-voltage detector 210 may be turned off to disconnect the + current supply line 212. Accordingly, the current applied to the coil 254 through the + current supply line 212 may be blocked.

When the current applied to the coil 254 of the parking air discharge valve 250 is blocked, the force acting on the first rod member 256a may be released, and the first rod member 256a may move in the inner direction of the branch line 34 by the elastic restoring force of the spring 252.

When the first rod member 256a moves inward along the branch line 34 by the elastic restoring force, the second rod member 256b may be fully inserted into the inner space of the branch line 34 through the opening 36 of the branch line 34 and the orifice hole 260 formed in the second rod member 256b may thus be interposed in the inner space of the branch line 34. Accordingly, the compressed air of the branch line 34 may be discharged through the orifice hole 260 of the second rod member 256b.

When the battery voltage Vbat is less than or equal to the reference voltage of 16V, the EPB controller 120 may be switched to an inoperable state. When the battery voltage Vbat is less than or equal to the reference voltage of 16V, the parking air discharge valve 250 of the emergency parking control device 200 may start to discharge the compressed air of the branch line 34 into the air through the orifice hole 260. As the compressed air is discharged into the air through the orifice hole 260, an air pressure of the parking air tank 30 and the EPB chamber 140 connected to the branch line 34 may gradually decrease, and when the air pressure reaches a certain level, the parking brake may operate, and the vehicle may be braked. In this way, when the EPB controller 120 is in the inoperable state due to a low-voltage state of the battery 20, the parking brake may operate with a time lag by the operation of the emergency parking control device 200 and the vehicle may then be braked. In the meantime, the driver may move the vehicle to a safe space.

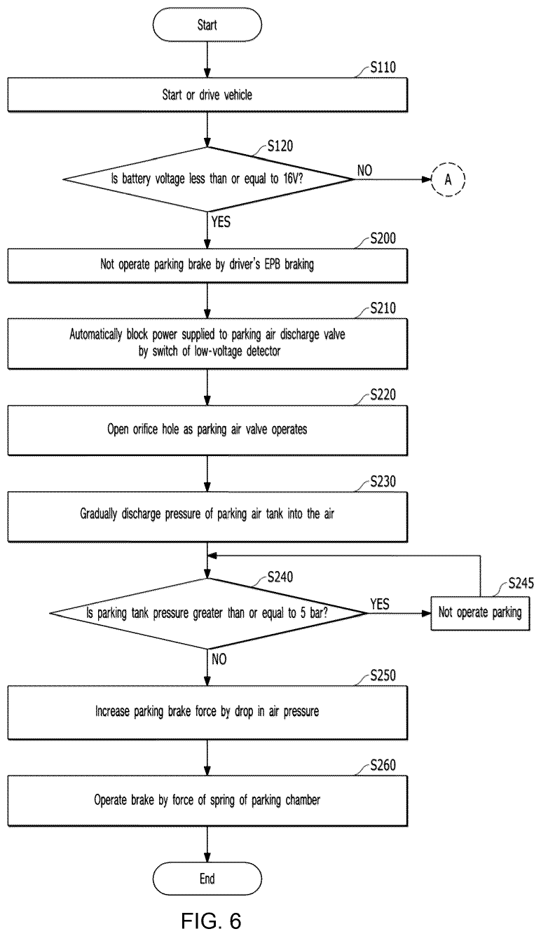

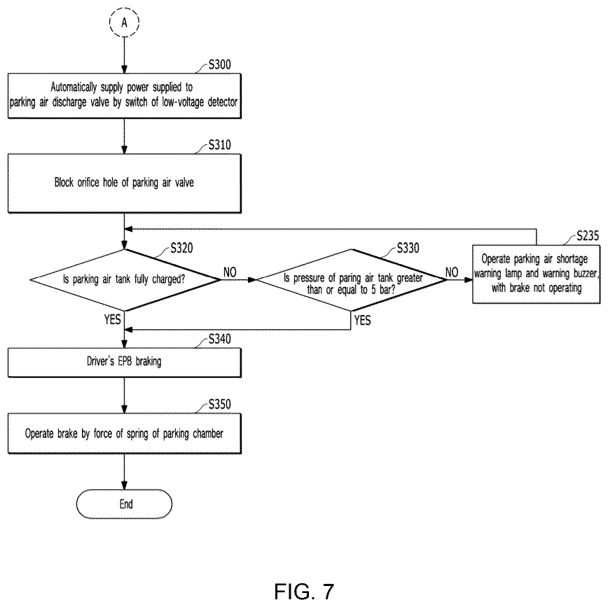

FIGS. 6 and 7 are flowcharts illustrating a vehicle parking control method according to an embodiment of the present disclosure. FIG. 6 is a flowchart illustrating a vehicle parking control method performed when a battery voltage Vbat is less than or equal to a reference voltage of 16V, and FIG. 7 is a flowchart illustrating a vehicle parking control method performed when the battery voltage Vbat exceeds the reference voltage of 16V.

Referring to FIG. 6, when a vehicle is started or is traveling in step S110, whether a battery voltage Vbat of the vehicle is less than or equal to a reference voltage of 16V may be detected in step S120. In this case, the low-voltage detector 210 of the emergency parking control device 200 may operate by detecting whether the battery voltage Vbat of the vehicle is less than or equal to the reference voltage of 16V.

When the battery voltage Vbat of the vehicle is less than or equal to the reference voltage of 16V, the parking brake may fail to engage when the driver attempts to activate it through the EPB system in step S200. This is because the EPB controller 120 of the EPB system, which is configured to output a “parking brake on” control signal according to a signal of the EPB switch 110 selected by the driver, is in an inoperable state when the battery voltage Vbat is less than or equal to 16V. Therefore, the parking brake using the EPB switch 110 may not be able to operate.

When the battery voltage Vbat of the vehicle is less than or equal to the reference voltage of 16V, the switch 216 of the low-voltage detector 210 may be turned off to block current to be applied to the coil 254 of the parking air discharge valve 250 in step S210.

When the current input to the coil 254 is stopped, the orifice hole 260 of the parking air discharge valve 250 may be opened in step S220. Accordingly, the compressed air in the branch line 34 may be discharged into the air through the orifice hole 260.

When the compressed air is discharged into the air according to conditions such as the size and number of orifice holes 260, an air pressure in the parking air tank 30 and the EPB chamber 140 may gradually decrease in step S230.

Whether the pressure of the parking air tank 30 is greater than or equal to a reference pressure, for example, 5 bar, may be checked in step S240, and when it is greater than or equal to 5 bar, the parking function may not operate in step S245.

When the pressure of the parking air tank 30 is less than 5 bar, the parking brake force may gradually increase by the pressure drop in step S250.

Subsequently, when the pressure of the parking air tank 30 becomes equal to an air pressure (or atmospheric pressure), the brake may be activated by an elastic force of the spring of the parking chamber 140 in step S260.

As described above, when the battery voltage Vbat is less than or equal to the reference voltage of 16V, the orifice hole 260 of the parking air discharge valve 250 may open, allowing the compressed air in the parking air tank 30 to be gradually discharged. Accordingly, the parking brake force may gradually increase in proportion to the pressure drop, allowing the brake to operate.

FIG. 7 is a flowchart illustrating a vehicle parking control method performed in a case (A) in which the battery voltage Vbat exceeds the reference voltage of 16V, in the step S120 of detecting whether the battery voltage Vbat of the vehicle is less than or equal to the reference voltage of 16V while the vehicle is started or traveling in step S110.

When the battery voltage Vbat exceeds the reference voltage of 16V, the switch 216 of the low-voltage detector 210 may be turned on and the current may then be automatically supplied to the coil 254 of the parking air discharge valve 250 in step S300. When the battery voltage Vbat exceeds the reference voltage of 16V, the EPB controller 120 of the EPB system may operate normally.

When the current is supplied to the coil 254, the orifice hole 260 of the parking air discharge valve 250 may be blocked in step S310. Accordingly, the branch line 34 may be maintained in a blocked state, and the parking brake function may be controlled according to the control of the EPB controller 120 of the EPB system.

The controller in the vehicle may check whether the parking air tank 30 is fully charged in step S320, and when it is not fully charged, may check whether the pressure is greater than or equal to a reference pressure, for example, 5 bar, in step S330. When the pressure of the parking air tank 30 is less than 5 bar, a parking air shortage warning lamp may be lit up and a warning buzzer may operate, and the parking function may not operate in step S335.

When the pressure of the parking air tank 30 is fully charged or in a state with 5 bar or greater even though it is not fully charged, the driver may execute an EPB provision function through the EPB switch 110 in step S340.

When the driver selects the EPB provision function through the EPB switch 110, the parking brake may operate by a force of the spring of the parking chamber 140 under the control of the EPB controller 120 of the EPB system in step S350.

As described above, when the battery voltage Vbat of the vehicle exceeds the reference voltage of 16V, the branch line 34 may remain blocked, and the parking brake function may be controlled under the control of the EPB controller 120 of the EPB system. In this case, when the pressure of the parking air tank 30 is less than 5 bar, the parking air shortage warning lamp may be lit up and the warning buzzer may operate.

According to embodiments of the present disclosure, an additional pipe for air discharge may be installed in a parking air tank for driving a parking brake, and when a vehicle is in a low-voltage state with a voltage less than or equal to a reference voltage, the additional pipe may be controlled to discharge compressed air from the parking air tank through an orifice hole, which may ensure the safety of the vehicle when the parking brake function using the EPB system is lost due to the low-voltage state.

The foregoing detailed description should not be construed as restrictive but as illustrative in all respects. The scope of the embodiments of the present disclosure should be determined by reasonable interpretation of the appended claims, and all changes and modifications within the equivalent scope of the present disclosure are included in the scope of the present disclosure.

What is claimed is:

1. A method of controlling parking of a vehicle, the method comprising:
detecting, by a low-voltage detector, whether a battery power supplied to an electronic parking brake (EPB) controller is less than or equal to a reference voltage, the EPB being configured to control a flow of compressed air to generate a brake force based on a pressure of the compressed air; and
if the battery power is detected to be less than or equal to the reference voltage, discharging, by a solenoid valve, the compressed air into atmosphere by opening at least one orifice hole.

2. The method of claim 1, wherein the detecting of whether the battery power is less than or equal to the reference voltage comprises:
entering an on state and supplying current if the battery power exceeds the reference voltage, and entering an off state and blocking the current supply if the battery power is less than or equal to the reference voltage,
wherein the discharging of the compressed air into atmosphere comprises:
when the current supply is blocked, opening the orifice hole by a solenoid valve to discharge the compressed air into atmosphere, and
when the current is supplied, blocking the discharging of the compressed air by the solenoid valve receiving the current.

3. The method of claim 1, wherein the vehicle comprises:
an air tank configured to store therein the compressed air;
a hydraulic line configured to transfer the compressed air of the air tank;
an EPB valve configured to receive the compressed air through the hydraulic line and block or pass the flow of the compressed air according to a control signal from the EPB controller;
an EPB chamber configured to generate a brake force based on the pressure of the compressed air supplied through the EPB valve;
a branch line branched from the hydraulic line; and
a solenoid valve interposed in the branch line and configured to open the at least one orifice hole to discharge the compressed air into atmosphere when the battery power is less than or equal to the reference voltage.

4. The method of claim 3, wherein the detecting of whether the battery power is less than or equal to the reference voltage comprises:
supplying current to the solenoid valve as a switch is turned on if the battery power exceeds the reference voltage, and blocking the current supply to the solenoid valve as the switch is turned off if the battery power is less than or equal to the reference voltage.

5. The method of claim 4, wherein the solenoid valve comprises:
a coil configured to receive the current under the control of the voltage detector;
a spring interposed in the coil; and
a rod configured to block the orifice hole by moving in a direction that presses the spring when the current is supplied to the coil, and open the orifice hole by moving in an opposite direction by an elastic restoring force of the spring when the current supply is blocked.

6. The method of claim 5, wherein the rod comprises:
a first rod member configured to move with a linear displacement outside the branch line based on whether the coil is energized;
a second rod member having the orifice hole formed therein, and inserted into an inner space of the branch line through an opening formed in the branch line to block the compressed air or open the orifice hole; and
a connecting member configured to connect the first rod member and the second rod member.

7. The method of claim 6, comprising:
supplying the current by the switch being turned on if the battery power exceeds the reference voltage; and
when the current is supplied to the coil of the solenoid valve and the first rod member moves in an outer direction of the branch line to press the spring, and the second rod member is pulled out through the opening formed in the branch line by the movement of the first rod member, closing the orifice hole.

8. The method of claim 6, comprising:
blocking the current supply by the switch being turned off if the battery power is less than or equal to the reference voltage; and
when the current supply to the coil of the solenoid valve is blocked and the first rod member moves in an inner direction of the branch line by the elastic restoring force of the spring, and the second rod member is inserted into the branch line through the opening formed in the branch line by the movement of the first rod member, opening the orifice hole.

9. The method of claim 8, comprising:
discharging the compressed air stored in the air tank outside through the orifice hole of the branch line;
reducing an air pressure in the air tank and the EPB chamber; and
generating a parking brake force by the reduced air pressure in the EPB chamber.

10. The method of claim 1, wherein the reference voltage is 16V.

11. A parking control system of a vehicle, comprising:
an electronic parking brake (EPB) controller configured to control a flow of compressed air to generate a brake force based on a pressure of the compressed air;
a low-voltage detector configured to detect whether a battery power supplied to the EPB controller is less than or equal to a reference voltage; and
a solenoid valve configured to discharge the compressed air into atmosphere if the battery power is detected to be less than or equal to the reference voltage.

12. The parking control system of claim 11, further comprising:
an air tank configured to store therein the compressed air;
a hydraulic line configured to transfer the compressed air of the air tank;
an EPB valve configured to receive the compressed air through the hydraulic line, and block or pass the flow of the compressed air according to a control signal from the EPB controller;
an EPB chamber configured to generate a brake force according to the pressure of the compressed air supplied through the EPB valve; and
a branch line branched from the hydraulic line,
wherein the solenoid valve is interposed in the branch line, and configured to discharge the compressed air into atmosphere by opening at least one orifice hole when the battery power is less than or equal to the reference voltage.

13. The parking control system of claim 12, wherein the low-voltage detector is configured to be turned on or off according to the battery power to supply or block current, and
the solenoid valve is configured to block or discharge the compressed air based on whether the current is supplied or blocked.

14. The parking control system of claim 13, wherein the low-voltage detector comprises:
a switch configured to be turned on to supply the current if the battery power exceeds the reference voltage, and be turned off to block the current supply if the battery power is less than or equal to the reference voltage.

15. The parking control system of claim 14, wherein the solenoid valve comprises:
a coil configured to receive the current under the control of the low-voltage detector;
a spring interposed in the coil; and
a rod configured to block the orifice hole by moving in a direction that presses the spring when the current is supplied to the coil, and open the orifice hole by moving in an opposite direction by an elastic restoring force of the spring when the current supply is blocked.

16. The parking control system of claim 15, wherein the rod comprises:
a first rod member configured to move with a linear displacement outside the branch line depending on whether the current is supplied to the coil;
a second rod member having the orifice hole formed therein, and inserted into an inner space of the branch line through an opening formed in the branch line to block the compressed air or open the orifice hole; and
a connecting member configured to connect the first rod member and the second rod member.

17. The parking control system of claim 16, wherein the rod is configured to:
if the current is supplied to the coil and the first rod member moves in an outer direction of the branch line to press the spring, and the second rod member is pulled out through the opening formed in the branch line by the movement of the first rod member, close the orifice hole.

18. The parking control system of claim 17, wherein the rod is configured to:
if the current supply to the coil is blocked, the first rod member moves in an inner direction of the branch line by the elastic restoring force of the spring, and the second rod member is inserted into the branch line through the opening formed in the branch line by the movement of the first rod member, open the orifice hole.

19. The parking control system of claim 15, wherein the low-voltage detector comprises:
a first current supply line configured to apply current to the coil; and
a second current supply line configured to receive the current of the coil,
wherein the switch is interposed in the first current supply line.

20. The parking control system of claim 11, wherein the reference voltage is 16V.
